(19) United States
(12) Patent Application Publication
(10) Pub. No.: US 2024/0215378 A1
(43) Pub. Date: Jun. 27, 2024

(54) METHOD OF MANUFACTURING DISPLAY DEVICE AND DISPLAY DEVICE MANUFACTURED BY THE SAME

(71) Applicant: Samsung Display Co., Ltd., Yongin-si (KR)

(72) Inventor: GEUNWOO YUG, Yongin-si (KR)

(21) Appl. No.: 18/494,706

(22) Filed: Oct. 25, 2023

(30) Foreign Application Priority Data
Dec. 22, 2022 (KR) 10-2022-0181747

(51) Int. Cl. H10K 59/80; B32B 3/26; B32B 5/02; B32B 15/04; B32B 37/16; B32B 38/00; H10K 59/12; H10K 59/88

(52) U.S. Cl. CPC H10K 59/80; B32B 3/263; B32B 5/02; B32B 15/04; B32B 37/16; B32B 38/105; H10K 59/1201; H10K 59/88; B32B 2260/021; B32B 2260/046; B32B 2305/076; B32B 2307/7376; B32B 2310/0843; B32B 2311/00; B32B 2457/206

(57) ABSTRACT

A method of manufacturing a display device includes forming a preliminary display panel including a light-emitting element on a substrate, and having a first dummy area at an outermost portion, attaching a preliminary support member under the preliminary display panel and having a second dummy area overlapping the first dummy area, removing an edge portion of the preliminary support member positioned around the second dummy area by irradiating a laser onto the preliminary support member, and forming a display panel and a support member having an end surface positioned on a virtual plane including an end surface of the display panel by irradiating another laser onto the preliminary support member, and by concurrently removing the first dummy area of the preliminary display panel and the second dummy area of the preliminary support member.

### CROSS-REFERENCE TO RELATED APPLICATION(S)

This application claims priority to, and the benefit of, Korean Patent Application No. 10-2022-0181747 filed on Dec. 22, 2022 in the Korean Intellectual Property Office (KIPO), the entire disclosure of which is incorporated by reference herein.

### BACKGROUND

### 1. Field

Embodiments relate to a method of manufacturing a display device, and to a display device manufactured by the method of manufacturing the display device.

### 2. Description of the related art

As information technology develops, the importance of display devices, which are communication media between users and information, is being highlighted. Accordingly, the use of display devices, such as a liquid crystal display device, an organic light-emitting display device, a plasma display device, and/or the like is increasing.

On the other hand, unlike a flat display device, a portion of a flexible display device may be bent. The flexible display device may include a display module having a flexible property, and a support member that allows the portion of the display device to be bent. The support member may have relatively greater rigidity than the flexible display device, and may be located under the flexible display device to support the flexible display device.

### SUMMARY

The disclosure may provide a method of manufacturing a display device.

The disclosure may provide a display device manufactured by the method of manufacturing the display device.

A method of manufacturing a display device according to one or more embodiments of the disclosure includes forming a preliminary display panel including a light-emitting element on a substrate, and having a first dummy area at an outermost portion, attaching a preliminary support member under the preliminary display panel and having a second dummy area overlapping the first dummy area, removing an edge portion of the preliminary support member positioned around the second dummy area by irradiating a laser onto the preliminary support member, and forming a display panel and a support member having an end surface positioned on a virtual plane including an end surface of the display panel by irradiating another laser onto the preliminary support member, and by concurrently removing the first dummy area of the preliminary display panel and the second dummy area of the preliminary support member.

The support member may include, a central portion having a flat bottom surface, and an edge portion including the end surface of the support member, and a connection surface connecting the end surface of the support member and the flat bottom surface of the central portion.

A thickness of the central portion of the support member may be different from a thickness of the edge portion of the support member.

The thickness of the central portion of the support member may be greater than the thickness of the edge portion of the support member.

The thickness of the central portion of the support member may be greater than or equal to about 90 micrometers and less than or equal to about 250 micrometers.

A minimum thickness of the edge portion of the support member may be less than or equal to about 20 micrometers.

The connection surface of the support member may have an inclined cross-sectional shape.

The connection surface of the support member may have a stepped cross-sectional shape.

The support member may include metal.

The support member may include fiber reinforced plastic.

A display device according to one or more embodiments includes a display panel including a light-emitting element above a substrate, and a support member under the display panel, and having an end surface on a virtual plane with an end surface of the display panel.

The support member may include a central portion having a flat bottom surface, and an edge portion including the end surface of the support member, and a connection surface connecting the end surface of the support member and the flat bottom surface of the central portion.

A thickness of the central portion of the support member is different from a thickness of the edge portion of the support member.

The thickness of the central portion of the support member may be greater than the thickness of the edge portion of the support member.

The thickness of the central portion of the support member may be greater than or equal to about 90 micrometers and less than or equal to about 250 micrometers.

A minimum thickness of the edge portion of the support member may be less than or equal to about 20 micrometers.

The connection surface of the support member may have an inclined cross-sectional shape.

The connection surface of the support member may have a stepped cross-sectional shape.

The support member may include metal.

The support member may include fiber reinforced plastic.

In a method of manufacturing the display device according to one or more embodiments the end surface of the support member may be positioned on the virtual plane including the end surface of the display panel, so that the support member may distribute an impact applied to a side surface of the display panel. Accordingly, the method of manufacturing the display device may improve a yield of the display device.

In addition, the display device manufactured by the method of manufacturing the display device may include the display panel and the support member. The support member may be located under the display panel. The support member may include the end surface positioned on the virtual plane including the end surface of the display panel. Accordingly, a lamination error between the display panel and the support member might not occur, and the support member may distribute the impact applied to the side surface of the display panel.

### BRIEF DESCRIPTION OF THE DRAWINGS

FIG. 1 is a front view of a display device according to one or more embodiments of the disclosure.

FIG. 2 is a cross-sectional view taken along the line I-I′ of FIG. 1.

FIG. 3 is an enlarged view of area A of FIG. 2.

FIG. 4 is a cross-sectional view illustrating the display panel included in the display device of FIG. 2.

FIG. 5 is a cross-sectional view illustrating a display device according to one or more other embodiments of the disclosure.

FIG. 6 is an enlarged view of area B of FIG. 5.

FIGS. 7, 8, 9, 10, and 11 are views illustrating a method of manufacturing the display device according to one or more embodiments of the disclosure.

FIG. 12 is a view illustrating a method of manufacturing the display device according to one or more other embodiments of the disclosure.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in different forms, and should not be construed as being limited to only the illustrated embodiments herein. Further, each of the features of the various embodiments of the present disclosure may be combined or combined with each other, in part or in whole, and technically various interlocking and driving are possible. Each embodiment may be implemented independently of each other or may be implemented together in an association. The described embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Further, various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and/or the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

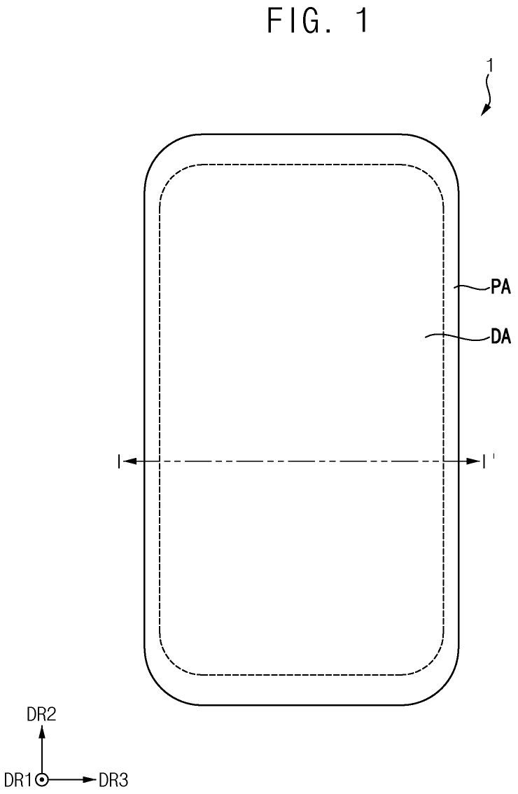

FIG. 1 is a front view of a display device 1 according to one or more embodiments of the disclosure.

Referring to FIG. 1, the display device 1 according to one or more embodiments of the disclosure may be divided into a display area DA and a peripheral area PA.

The display area DA may be an area where an image is displayed. For example, the display area DA may be an area for emitting light of various colors. A direction in which the image is displayed may be referred to as a front direction (e.g., a first direction DR1).

The peripheral area PA may be positioned around the display area DA (e.g., in plan view). For example, the peripheral area PA may surround the display area DA.

The display device 1 may have various shapes in a plan view. For example, the display device 1 may have a rectangular shape in the plan view. In this case, a plane may be defined by a second direction DR2 and a third direction DR3. Each of the second and third directions DR2 and DR3 may cross the first direction DR1. For example, each of the second and third directions DR2 and DR3 may be perpendicular to the first direction DR1.

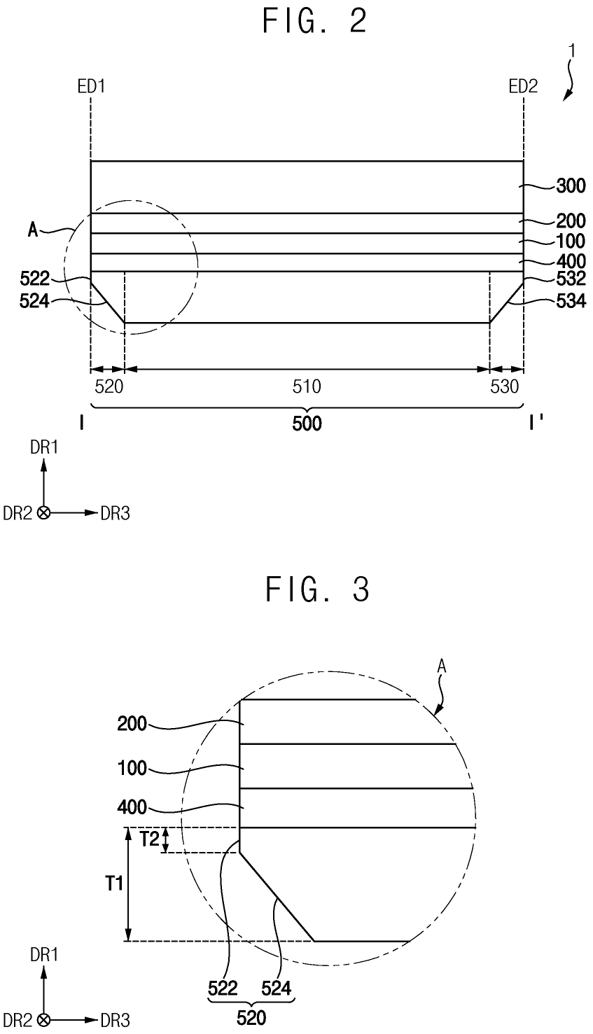

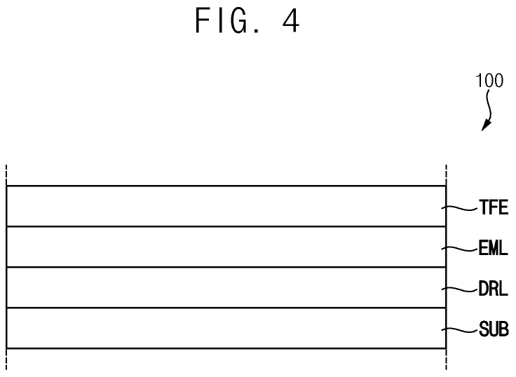

FIG. 2 is a cross-sectional view taken along the line I-I′ of FIG. 1. FIG. 3 is an enlarged view of area A of FIG. 2. FIG. 4 is a cross-sectional view illustrating the display panel included in the display device of FIG. 2.

Referring to FIGS. 2, 3, and 4, the display device 1 according to one or more embodiments of the disclosure may include a display panel 100, an upper structure 200, a cover window 300, a lower structure 400, and a support member 500. For example, along the first direction DR1, the lower structure 400 may be located on the support member 500, the display panel 100 may be located on the lower structure 400, the upper structure 200 may be located on the display panel 100, and the cover window 300 may be located on the upper structure 200.

The display panel 100 may include a plurality of pixels, and light emitted from the plurality of pixels may be combined to display the image. For example, the display panel 100 may include a substrate SUB, a device wiring layer DRL, a display layer EML, and an encapsulation layer TFE.

The substrate SUB may include a material having flexible characteristics. For example, the substrate SUB may include polyethersulphone (PS), polyacrylate (PAR), polyetherimide (PEI), polyethylene naphthalate (PEN), polyphenylene sulfide (PPS), polycarbonate (PC), cellulose acetate propionate, and/or the like. These may be used alone or in combination with each other. However, the disclosure is not limited thereto, and the substrate SUB may include a material having rigid characteristics.

The device wiring layer DRL may be located on the substrate SUB. The device wiring layer DRL may include a circuit for driving the display layer EML. For example, the device wiring layer DRL may include a thin film transistor, a capacitor, and various wires.

The display layer EML may be located on the device wiring layer DRL. The display layer EML may include a light-emitting element. For example, the display layer EML may include an organic light-emitting diode (OLED). The display layer EML may emit light with various luminance according to a driving signal transmitted from the device wiring layer DRL. However, the disclosure is not limited thereto, and the display layer EML may be an inorganic display layer, an organic-inorganic display layer, a quantum dot display layer, a micro-LED display layer, and/or the like.

The encapsulation layer TFE may be located on the display layer EML. The encapsulation layer TFE may protect the light-emitting element. For example, the encapsulation layer TFE may include at least one inorganic layer or organic layer. The encapsulation layer TFE may have a multi-layer structure. For example, the encapsulation layer TFE may have a structure in which a first inorganic layer, an organic layer, and a second inorganic layer are stacked. An upper surface of the organic layer may be flat, and the second inorganic layer may include a crack-resistant material to more firmly protect the light-emitting element than a display device of a comparative example including only the organic layer.

The upper structure 200 may be located on the display panel 100.

In one or more embodiments, the upper structure 200 may include a polarization layer. The polarization layer may reduce reflection of external light of the display device 1. For example, the external light may pass through the polarization layer, may be reflected from a lower portion of the polarization layer (e.g., the display panel 100), and then may pass through the polarization layer again. In this case, a phase of the external light may be changed by passing through the polarization layer twice. Accordingly, destructive interference may occur between incident light and reflected light. Accordingly, the reflection of the external light in the display device 1 may be reduced to improve visibility. For example, the polarization layer may include various synthetic resins capable of changing the phase of the external light.

The upper structure 200 may omit the polarization layer. In this case, the display device 1 may further include a black pixel-defining layer (BPDL) including a black material and a color filter. As the polarization layer is omitted in the display device 1, light-transmittance of the display device 1 may increase by about 33% when compared to a display device according to the comparative example including the polarization layer. In addition, because the polarization layer is omitted in the display device 1, power consumption may be reduced by about 25% when compared to the display device according to the comparative example including the polarization layer at a same brightness.

In one or more other embodiments, the upper structure 200 may include a damping layer. When a portion of the display device 1 is deformed, a portion of the damping layer corresponding to the deformed portion may be deformed, and thus, a Young's modulus may increase. The damping layer may reduce or prevent damage to the display device 1 by absorbing energy due to an external impact applied to the display device 1. For example, the damping layer may include thermoplastic urethane (TPU) or thermoplastic olefin (TPO). These may be used alone or in combination with each other. However, the disclosure is not limited thereto, and the damping layer may include various elastomers having shear thickening characteristic. The shear thickening characteristic may be defined as a characteristic in which the Young's modulus increases when the damping layer changes according to the stress applied to the damping layer.

The cover window 300 may be located on the upper structure 200. The cover window 300 may protect the display panel 100 from external impact. For example, the cover window 300 may include transparent polyimide (colorless polyimide), ultra-thin glass (UTG), polyethylene terephthalate (PET), polyimide (PI), polyether, polyethersulphone (PS), polyacrylate (PAR), polyetherimide (PEI), polyethylene naphthalate (PEN), polyphenylene sulfide (PPS), polycarbonate, PC, and/or the like. These may be used alone or in combination with each other. However, the disclosure is not limited thereto, and the cover window 300 may include various materials that are transparent and hard.

The lower structure 400 may be located under the display panel 100. In one or more embodiments, the lower structure 400 may include a cushion layer. The cushion layer may protect the display panel 100 from external impact. For example, the cushion layer may include acrylic resin, polyurethane, latex, and/or the like. These may be used alone or in combination with each other. However, the disclosure is not limited thereto, and the cushion layer may include various materials capable of absorbing and alleviating external impact.

The support member 500 may be located under the lower structure 400, and may support the display panel 100.

In one or more embodiments, the support member 500 may include metal. For example, the support member 500 may include various metals, such as invar, nobinite, and stainless. However, the disclosure is not limited thereto, and the support member 500 may include an alloy, such as steel use stainless (SUS), nickel-titanium (Ni—Ti), nickel-aluminum (Ni—Al), copper-Zinc-nickel (Cu—Zn—Ni), copper-aluminum-nickel (Cu—Al—Ni), copper-aluminum-manganese (Cu—Al—Mn), titanium-nickel-copper-molybdenum (Ti—Ni—Cu—Mo), cobalt-nickel-gallium: iron (Co—Ni—Ga: Fe), silver-nickel (Ag—Ni), gold-cadmium (Au—Cd), iron-platinum (Fe—Pt), nickel (Fe—Ni), indium-cadmium (In—Cd), and/or the like. These may be used alone or in combination with each other. However, the disclosure is not limited thereto, and the support member 500 may include various materials having restoring force.

The display device 1 may further include a touch sensor capable of detecting a user's touch operation on the support member 500 including the metal. For example, the display device 1 may include the touch sensor and/or the like located on the display panel 100. The touch sensor may be directly implemented inside the display panel 100. Alternatively, the touch sensor may be implemented on a separate substrate and located on the display panel 100.

In one or more other embodiments, the support member 500 may include fiber reinforced plastic (FRP). For example, the support member 500 may include carbon fiber reinforced plastic (CFRP), glass fiber reinforced plastic (GFRP), and/or the like. These may be used alone or in combination with each other.

The display device 1 may further include a digitizer and a magnetic member under the support member 500 including the fiber reinforced plastic. The digitizer may convert coordinates of an input unit into digital data when the input unit contacts the display device 1. For example, the input unit may be a touch pen. The magnetic member may be located under the digitizer, and may include magnetic powder. For example, the digitizer may use an electromagnetic resonance (EMR) method. As the input unit approaches the display device 1, the magnetic member may induce electromagnetic resonance.

In one or more embodiments, the support member 500 may include a central portion 510 and an edge portion 520 and/or 530. For example, the edge portion 520 and/or 530 may surround the central portion 510 in the plan view. The plane may be defined by the second direction DR2 and the third direction DR3.

In one or more embodiments, the central portion 510 may have a flat bottom surface. A thickness T1 of the central portion 510 may be greater than or equal to about 90 μm and may be less than or equal to about 250 μm. The thickness T1 of the central portion 510 may be defined as a thickness from the flat bottom surface to a top surface facing the bottom surface.

When the thickness T1 of the central portion 510 is less than about 90 μm, the support member 500 might not suitably support the display panel 100. On the other hand, when the thickness T1 of the central portion 510 exceeds about 250 μm, a weight of the display device 1 may increase.

In one or more embodiments, the edge portion 520 and/or 530 may include an end surface 522 and/or 532 and a connection surface 524 and/or 534. The end surface 522 and/or 532 may be positioned on a virtual plane including an end surface ED1 and/or ED2 of the display panel 100. The connection surface 524 and/or 534 may connect the flat bottom surface of the central portion 510 and the end surface 522 and/or 532.

In one or more embodiments, the connection surface 524 and/or 534 may have an inclined cross-sectional shape. Accordingly, the thickness of the edge portion 520 and/or 530 may gradually thicken from the central portion 510 toward the edge portion 520 and/or 530. For example, the thickness T1 of the central portion 510 may be greater than or equal to about 90 μm and less than or equal to about 250 μm. On the other hand, a minimum thickness T2 of the edge portion 520 and/or 530 may be less than or equal to about 20 μm. The minimum thickness T2 of the edge portion 520 and/or 530 may mean the minimum thickness of the end surface 522 and/or 532. In other words, a width of the end surface 522 and/or 532 in the first direction DR1 may be less than or equal to about 20 μm.

Heat or sparks may be generated during processing of the edge portion 520 and/or 530. When the minimum thickness T2 of the edge portion 520 and/or 530 exceeds about 20 μm, a heat affected zone (HAZ) may be generated in the display panel 100 due to the heat, or a shrinkage defect due to the spark may occur.

In a case of the display device according to the comparative example, the end surface of the support member might not be positioned on the virtual plane including the end surface of the display panel. Accordingly, when the external impact is applied to one end of the display panel not covered by the support member, a dark spot or the like may occur on the display panel.

On the other hand, the display device 1 according to one or more embodiments of the disclosure may include the support member 500 including the end surface 522 and/or 532 positioned on the virtual plane including the end surface ED1 and/or ED2 of the display panel 100. In other words, the end of the display panel 100 and the end of the support member 500 might not have a step. Accordingly, because the end of the display panel 100 is not exposed to the outside, the display device 1 including the display panel 100, which is more robustly protected from external impact, may be provided.

In addition, the display device 1 may include the support member 500 having the thickness T1 of the central portion 510 of about 90 μm or more and about 250 μm or less. Accordingly, sagging of the display panel 100 included in the display device 1 may be reduced or prevented and a lightweight display device 1 may be provided.

In addition, the display device 1 may include the support member 500 in which the minimum thickness T2 of the edge portion 520 and/or 530 is less than or equal to about 20 μm. Accordingly, in the process of manufacturing the display device 1, the display device 1 might not be defective due to avoiding the heat or the spark.

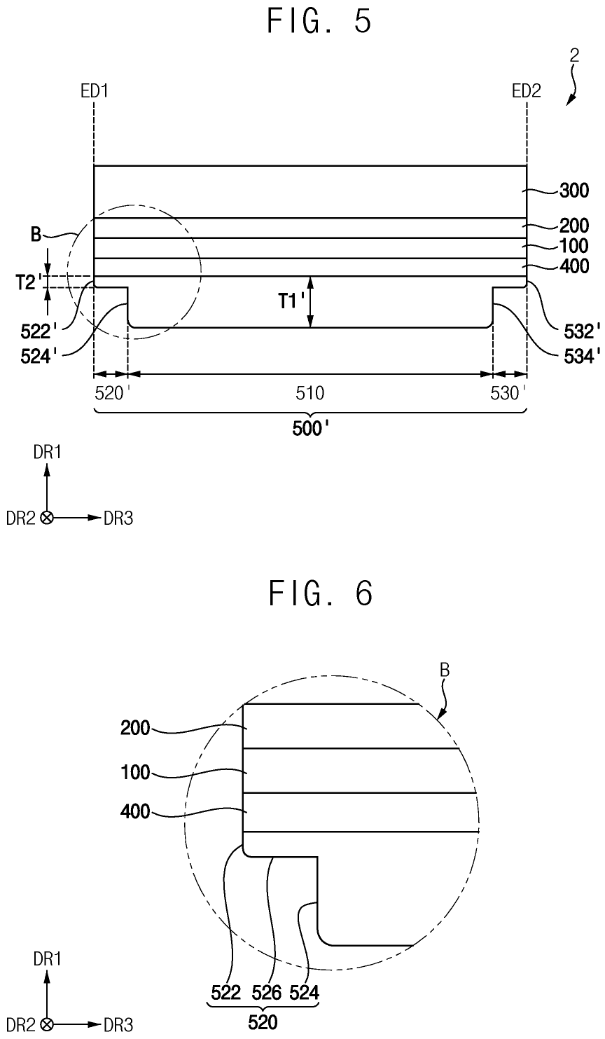

FIG. 5 is a cross-sectional view illustrating a display device 2 according to one or more other embodiments of the disclosure. FIG. 6 is an enlarged view of area B of FIG. 5.

Referring to FIGS. 5 and 6, the display device 2 according to one or more other embodiments of the disclosure may include the display panel 100, the upper structure 200, the cover window 300, the lower structure 400, and a support member 500′. For example, along the first direction DR1, the lower structure 400 may be located on the support member 500′, the display panel 100 may be located on the lower structure 400, the upper structure 200 may be located on the display panel 100, and the cover window 300 may be located on the upper structure 200. Hereinafter, the display device 2 described with reference to FIGS. 5 and 6 may be substantially the same as or similar to the display device 1 described with reference to FIGS. 1, 2, 3, 4, and 5 except for a shape of the support member 500′. Hereinafter, redundant descriptions will be omitted or simplified.

The support member 500′ may be located under the lower structure 400, and may support the display panel 100.

In one or more embodiments, the support member 500′ may include metal. In this case, the display device 2 may further include the touch sensor capable of detecting the user's touch operation on the support member 500′. For example, the display device 2 may include the touch sensor and/or the like located on the display panel 100. The touch sensor may be directly implemented inside the display panel 100. Alternatively, the touch sensor may be implemented on the separate substrate, and may be located on the display panel 100.

In one or more other embodiments, the support member 500′ may include fiber reinforced plastic (FRP). For example, the support member 500′ may include carbon fiber reinforced plastic (CFRP), glass fiber reinforced plastic (GFRP), and/or the like. These may be used alone or in combination with each other. In this case, the display device 2 may further include the digitizer and the magnetic member under the support member 500′ including the fiber reinforced plastic. The digitizer may convert the coordinates of the input unit into the digital data when the input unit contacts the display device 2. For example, the input unit may be the touch pen. The magnetic member may be located under the digitizer, and may include the magnetic powder. For example, the digitizer may use the electromagnetic resonance (EMR) method. As the input unit approaches the display device 2, the magnetic member may induce the electromagnetic resonance.

In one or more embodiments, the support member 500′ may include the central portion 510 and an edge portion 520′ and/or 530′. For example, the edge portion 520′ and/or 530′ may surround the central portion 510 in the plan view. The plane may be defined by the second direction DR2 and the third direction DR3.

In one or more embodiments, the central portion 510 may have the flat bottom surface. A thickness T1′ of the central portion 510 may be greater than or equal to about 90 μm and less than or equal to about 250 μm. The thickness T1′ of the central portion 510 may be defined as the thickness from the flat bottom surface to the top surface facing the bottom surface.

When the thickness T1′ of the central portion 510 is less than about 90 μm, the support member 500′ may not support the display panel 100. On the other hand, when the thickness T1′ of the central portion 510 exceeds about 250 μm, the weight of the display device 2 may increase.

In one or more embodiments, the edge portion 520′ and/or 530′ may include an end surface 522′ and/or 532′ and a connection surface 524′ and/or 534′. The end surface 522′ and/or 532′ may be positioned on the virtual plane including an end surface ED1 and/or ED2 of the display panel 100. The connection surface 524′ and/or 534′ may connect the flat bottom surface of the central portion 510 and the end surface 522′ and/or 532′.

In one or more embodiments, the edge portion 520′ and/or 530′ may further include a flat surface 526 located between the end surface 522′ and the connection surface 524′. The flat surface 526 may be thinner than the central portion 510 to reduce a laser-processing time (e.g., a laser LA shown in FIG. 8).

In one or more embodiments, the connection surface 524′ and/or 534′ may have the inclined cross-sectional shape. Accordingly, the thickness of the edge portion 520′ and/or 530′ may be different from the thickness T1′ of the central portion 510. For example, the thickness T1′ of the central portion 510 may be greater than or equal to about 90 μm and less than or equal to about 250 μm. On the other hand, a minimum thickness T2′ of the edge portion 520′ and/or 530′ may be less than or equal to about 20 μm. The minimum thickness T2′ of the edge portion 520′ and/or 530′ may mean the minimum thickness of the end surface 522′ and 532′. In other words, a width of the end surface 522′ and/or 532′ in the first direction DR1 may be less than or equal to about 20 μm.

Heat or sparks may be generated during processing of the edge portion 520′ and/or 530′. When the minimum thickness T2′ of the edge portion 520′ and/or 530′ exceeds about 20 μm, the heat affected zone (HAZ) due to the heat may be generated in the display panel 100, and/or a shrinkage defect due to the spark, may occur.

In the case of the display device according to the comparative example, the end surface of the support member might not be positioned on the virtual plane including the end surface of the display panel. Accordingly, when the external impact is applied to the one end of the display panel not covered by the support member, the dark spot or the like may occur on the display panel.

On the other hand, the display device 2 according to one or more embodiments of the disclosure may include the support member 500′ including the end surface 522′ and/or 532′ positioned on the virtual plane including the end surface ED1 and/or ED2 of the display panel 100. In other words, the end of the display panel 100 and the end of the support member 500′ might not have the step. Accordingly, because the end of the display panel 100 is not exposed to the outside, the display device 2 including the display panel 100, which is more robustly protected from external impact, may be provided.

In addition, the display device 2 may include the support member 500′ having the thickness T1′ of the central portion 510 of about 90 μm or more and about 250 μm or less. Accordingly, the sagging of the display panel 100 included in the display device 2 may be reduced or prevented, and the lightweight display device 2 may be provided.

In addition, the display device 2 may include the support member 500′ in which the minimum thickness T2′ of the edge portion 520′ and/or 530′ is less than or equal to about 20 μm. Accordingly, in the process of manufacturing the display device 2, the display device 2 might not be defective due to the heat or the spark.

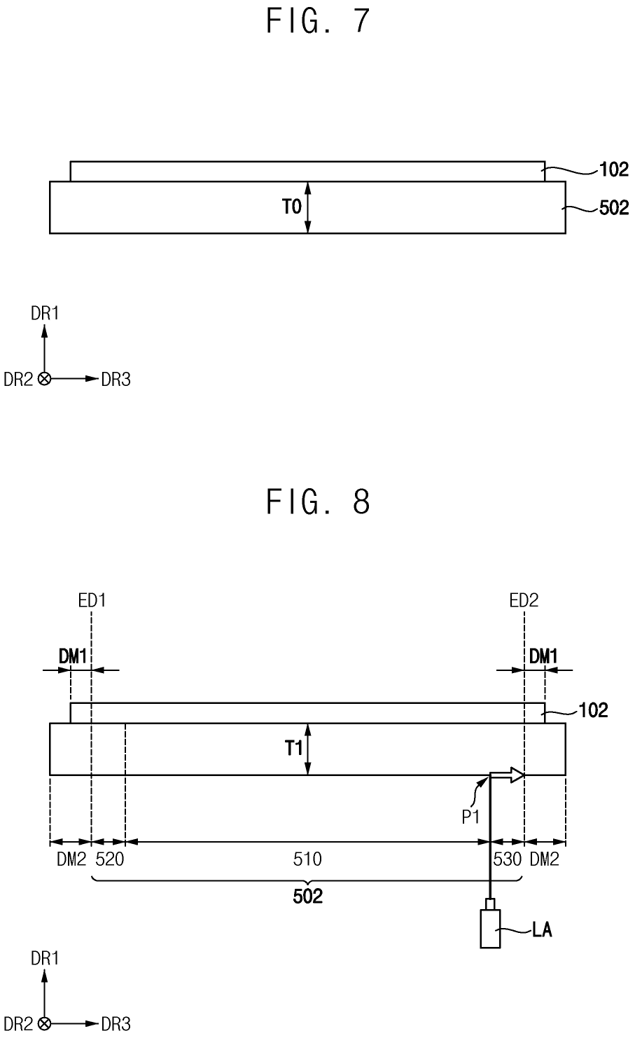

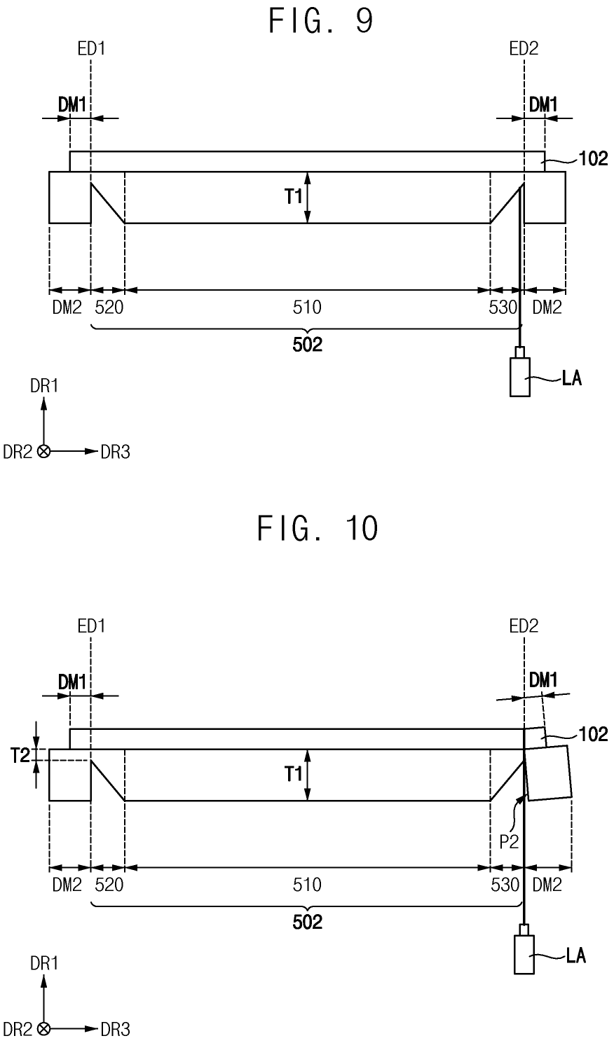

FIGS. 7, 8, 9, 10, and 11 are views illustrating a method of manufacturing the display device according to one or more embodiments of the disclosure. For convenience of explanation, the upper structure 200, the cover window 300, and the lower structure 400 located above and below the display panel 100 are omitted. Hereinafter, descriptions overlapping with the display device 1 and/or 2 are described with reference to FIGS. 1, 2, 3, 4, 5, and 6 will be omitted or simplified.

Referring to FIG. 7, a preliminary support member 502 may be attached under a preliminary display panel 102 after forming the preliminary display panel 102.

As described above with reference to FIG. 4, the preliminary display panel 102 may be formed by sequentially stacking the device wiring layer DRL, the display layer EML, and the encapsulation layer TFE on the substrate SUB. As described above, the light-emitting element formed on the substrate may be formed at the display layer EML.

The preliminary display panel 102 may have a first dummy area DM1 positioned at an outermost portion. The preliminary display panel 102 may be irradiated while moving a laser along a predetermined cutting line. Accordingly, a display panel having the first dummy area DM1 removed may be formed.

As described above with reference to FIGS. 1, 2, 3, 4, and 5, the preliminary support member 502 may include metal or fiber reinforced plastic (FRP).

The preliminary support member 502 may be attached under the preliminary display panel 102. When attaching the preliminary support member 502 to the preliminary display panel 102, an alignment error of about 100 μm may occur. Considering the alignment error, the preliminary support member 502 may be formed to be greater (e.g., to have a greater area) than the preliminary display panel 102.

The preliminary support member 502 may have a second dummy area DM2 positioned at the outermost portion. The second dummy area DM2 may overlap the first dummy area DM1 (e.g., in the thickness direction DR1).

To support the preliminary display panel 102, a thickness T0 of the preliminary support member 502 may be formed to be greater than or equal to about 90 μm and less than or equal to about 250 μm. When the thickness T0 of the preliminary support member 502 is less than about 90 μm, the display panel formed by removing the end portion of the preliminary display panel 102 may not be suitably supported. On the other hand, when the thickness T0 of the preliminary support member 502 exceeds about 250 μm, the weight of the display device may unsuitably increase.

Referring to FIGS. 8, 9, and 10, only a portion of the preliminary support member 502 may be first removed by first irradiating a laser LA. For example, only the portion of the edge portion 520 and/or 530 may be first removed by irradiating the laser LA onto the preliminary support member 502. The edge portion of the preliminary support member 502 may correspond to the edge portion 520, 530, 520′, and/or 530′ of the support member 500 or 500′ described above with reference to FIGS. 1, 2, 3, 4, 5, and 6.

The preliminary support member 502 may have a shape in which the central portion 510 is surrounded by the edge portion 520 and/or 530, and the edge portion 520 and/or 530 is surrounded by the second dummy area DM2. The laser LA may be irradiated onto the preliminary support member 502. In other words, the laser LA may be irradiated from the preliminary support member 502 toward the preliminary display panel 102.

The first irradiation may be a step of continuously irradiating the laser LA having a first energy. The laser LA having the first energy may be irradiated at a first position P1. The first position P1 may be a boundary between the central portion 510 and the edge portion 520 and/or 530. The first position P1 may be determined as a position where the sagging of the display panel may be reduced or prevented by the central portion 510 even when the thickness of the edge portion 520 and/or 530 is reduced. The first energy may be sufficient energy to remove the corresponding portion of the preliminary support member 502 including the metal or the fiber reinforced plastic.

As the laser LA is irradiated to the preliminary support member 502 while moving from the first position P1 to a second position P2, only the portion of the preliminary support member 502 may be removed first. In other words, the laser LA may be irradiated while moving in a direction from the central portion 510 toward the edge portion 520 and/or 530 starting from a position (e.g., a predetermined position, such as the first position P1 of FIG. 8). Accordingly, the portion of the edge portion 520 and/or 530 may be removed.

The second position P2 may be a position where the edge portion 520 and/or 530 has the minimum thickness T2. For example, even if the preliminary display panel 102 and the preliminary support member 502 are concurrently or substantially simultaneously removed using the laser LA at the second position P2, the preliminary display panel 102 might not be damaged by the heat or the spark.

As described above with reference to FIG. 7, to support the preliminary display panel 102, the thickness T0 of the preliminary support member 502 may be formed to be greater than or equal to about 90 μm and less than or equal to about 250 μm.

When the preliminary support member 502 has the thickness exceeding about 20 μm, even if the preliminary display panel 102 and the preliminary support member 502 are removed at a same time, the defect due to the heat or the spark in the preliminary display panel 102 might not occur.

On the other hand, if the preliminary support member 502 has a thickness of about 20 μm or less, even if the preliminary display panel 102 and the preliminary support member 502 are removed at the same time, the defect due to the heat or the spark in the preliminary display panel 102 might not occur.

To this end, only the portion of the preliminary support member 502 may be first removed between the first position P1 and the second position P2. Accordingly, the thickness of the edge portion 520 and/or 530 and the thickness T1 of the central portion 510 may be formed differently. For example, the minimum thickness T2 of the edge portion 520 and/or 530 may be formed to be less than the thickness T1 of the central portion 510. The minimum thickness T2 of the edge portion 520 and/or 530 may be formed to be about 20 μm or less. Accordingly, even if the preliminary display panel 102 and the preliminary support member 502 are concurrently or substantially simultaneously removed, the defect due to the heat or the spark in the preliminary display panel 102 might not occur.

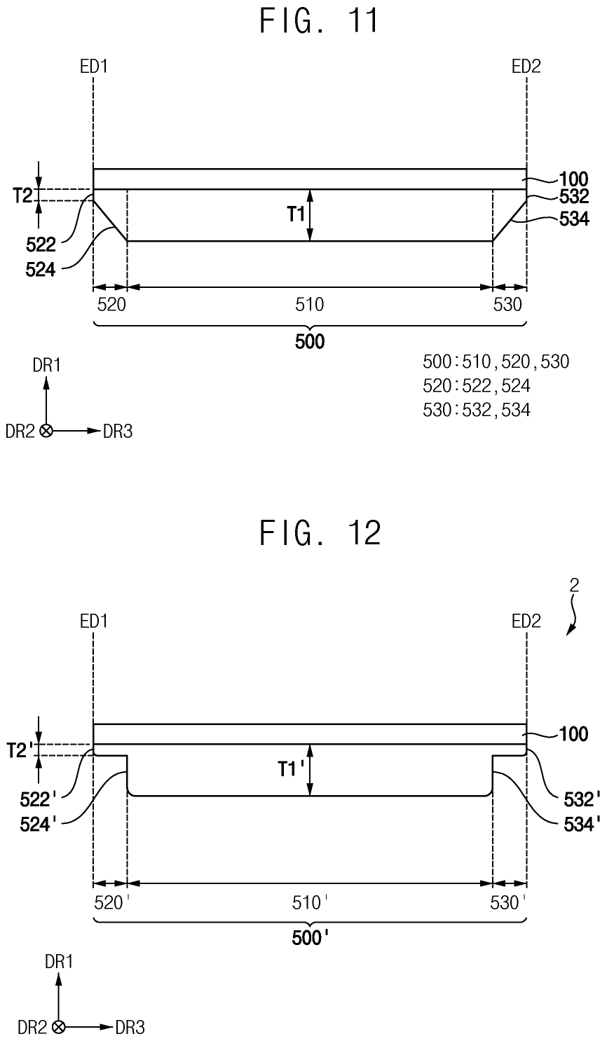

Referring to FIGS. 10 and 11, the first dummy area DM1 of the preliminary display panel 102 and the second dummy area DM2 of the preliminary support member 502 may be concurrently or substantially simultaneously removed by a secondary irradiating of the laser LA. For example, the preliminary support member 502 may be irradiated with the laser LA to concurrently or substantially simultaneously remove the first dummy area DM1 of the preliminary display panel 102 and the second dummy area DM2 of the preliminary support member 502. The display panel 100 and the support member 500 may be formed. The end surface 522 or 533 of the support member 500 may be positioned on the virtual plane including the end surface ED1 and/or ED2 of the display panel 100.

The secondary irradiation may be a step of continuously irradiating the laser LA having a second energy. The laser LA having the second energy may be irradiated at the second position P2. As described above, the second position P2 may be a position where the edge portion 520 and/or 530 has the minimum thickness T2. Because the preliminary display panel 102 and the preliminary support member 502 may be concurrently or substantially simultaneously removed at the second position P2, the laser LA may have the second energy that is less than the first energy.

The first dummy area DM1 of the preliminary display panel 102 and the second dummy area DM2 of the preliminary support member 502 may be concurrently or substantially simultaneously removed by irradiating the laser LA at the second position P2. Through this, the support member 500 having the end surface 522 and/or 532 positioned on the virtual plane including the display panel 100 and the end surface ED1 and/or ED2 of the display panel 100 may be formed. In other words, a step difference between the end surface ED1 and/or ED2 of the display panel 100 and the end surface 522 and/or 532 of the support member 500 may be removed. Accordingly, the support member 500 may distribute the impact applied to the side surface of the display panel 100.

The support member 500 may include the central portion 510 and the edge portion 520 and/or 530. In one or more embodiments, the central portion 510 may have the flat bottom surface, and the edge portion 520 and/or 530 may include the end surface 522 and/or 532 and the connection surface 524 and/or 534. The end surface 522 and/or 532 may be positioned on the virtual plane including the end surface ED1 and/or ED2 of the display panel 100. The connection surface 524 and/or 534 may connect the flat bottom surface of the central portion 510 and the end surface 522 and/or 532.

In one or more embodiments, the connection surface 524 and/or 534 may have the inclined cross-sectional shape. Accordingly, the thickness of the edge portion 520 and/or 530 may gradually thicken from the central portion 510 toward the edge portion 520 and/or 530. For example, the minimum thickness T2 of the edge portion 520 and/or 530 may be less than or equal to about 20 μm. In other words, the width of the end surface 522 and/or 532 in the first direction DR1 may be less than or equal to about 20 μm.

In a case of a method of manufacturing a display device according to the comparative example, after forming of a support member by firstly cutting a preliminary support member, the support member may be attached under the display panel. In this case, the lamination error may occur between the display panel and the support member. Accordingly, one end of the display panel may be exposed to the outside. At the one end of the display panel exposed to the outside, defects, such as shrinkage, may occur due to the external impact.

On the other hand, in a case of the method of manufacturing the display device according to one or more embodiments of the disclosure, the preliminary support member 502 may be attached under the preliminary display panel 102, and then the preliminary support member 502 and the preliminary display panel 102 may be removed at the same time. Therefore, even if the preliminary display panel 102 and the preliminary support member 502 are not accurately attached, the lamination error may not occur. In other words, there may be no step between the end surface ED1 and/or ED2 of the display panel 100 and the end surface 522 and/or 532 of the support member 500.

In addition, in the case of the method of manufacturing the display device according to one or more embodiments of the disclosure, the portion of the preliminary support member 502 may be removed first. The preliminary display panel 102 and the preliminary support member 502 may be concurrently or substantially simultaneously removed at the position where the minimum thickness T2 of the edge portion 520 and/or 530 is about 20 μm or less. Accordingly, the defect due to the heat or the spark might not occur in the display panel 100.

FIG. 12 is a view illustrating a method of manufacturing the display device 2 according to one or more other embodiments of the disclosure. Hereinafter, descriptions overlapping with the method of manufacturing the display device are described with reference to FIGS. 7, 8, 9, 10, and 11 will be omitted or simplified.

Referring to FIGS. 8, 9, 10, 11, and 12, the preliminary support member 502 may be attached under the preliminary display panel 102 after forming the preliminary display panel 102.

Next, the laser LA is irradiated to the preliminary support member 502 while moving from the first position P1 to the second position P2, only the portion of the preliminary support member 502 may be removed first. Through this, the thickness of the edge portion 520′ and/or 530′ and the thickness T1 of the central portion 510′ may be formed to have different thicknesses. For example, the thickness T1′ of the central portion 510′ may be formed to be greater than the thickness of the edge portion 520′ and/or 530′. Accordingly, the thickness of the edge portion 520′ and/or 530′ and the thickness T1′ of the central portion 510′ may differ from each other. In one or more embodiments, the thickness T1′ of the central portion 510′ may be formed to be greater than or equal to about 90 μm and less than or equal to about 250 μm, and the minimum thickness T2′ of the edge portion 520′ and/or 530′ may be formed to be less than or equal to about 20 μm.

Next, the first dummy area DM1 of the preliminary display panel 102 and the second dummy area DM2 of the preliminary support member 502 may be concurrently or substantially simultaneously removed by irradiating the laser LA at the second position P2. Through this, the support member 500′ having the end surface 522′ and/or 532′ positioned on the virtual plane including the display panel 100, and the end surface ED1 and/or ED2 of the display panel 100, may be formed. Accordingly, the support member 500′ may distribute the impact applied to the side surface of the display panel 100.

The support member 500′ may include the central portion 510′ and the edge portion 520′ and/or 530′. In one or more embodiments, the central portion 510′ may have the flat bottom surface, and the edge portion 520′ and/or 530′ may include the end surface 522′ and/or 532′ and the connection surface 524′ and/or 534′. The end surface 522′ and/or 532′ may be positioned on the virtual plane including the end surface ED1 and/or ED2 of the display panel 100. The connection surface 524′ and/or 534′ may connect the flat bottom surface of the central portion 510′ and the end surface 522′ and/or 532′.

In one or more embodiments, the connection surface 524′ and/or 534′ may have the inclined cross-sectional shape. Accordingly, the thickness of the edge portion 520′ and/or 530′ may differ from the thickness of the central portion 510′. For example, the minimum thickness T1′ of the central portion 510′ may be greater than or equal to about 90 μm and less than or equal to about 250 μm. On the other hand, the minimum thickness T2′ of the edge portion 520′ and/or 530′ may be less than or equal to about 20 μm. In other words, the width of the end surface 522′ and/or 532′ in the first direction DR1 may be less than or equal to about 20 μm. Accordingly, the defect due to the heat or the spark might not occur in the display panel 100.

The disclosure of the display device may be applied to a computer, a notepad, a cell phone, a smartphone, a smart pad, a PMP, a PDA, a MP3 player, and/or the like.

Although the embodiments have been described with reference to the drawings, the illustrated embodiments are examples, and may be modified and changed by a person having ordinary knowledge in the relevant technical field without departing from the technical spirit described in the following claims, with functional equivalents thereof to be included therein.

What is claimed is:

1. A method of manufacturing a display device, the method comprising:
forming a preliminary display panel comprising a light-emitting element on a substrate, and having a first dummy area at an outermost portion;
attaching a preliminary support member under the preliminary display panel and having a second dummy area overlapping the first dummy area;
removing an edge portion of the preliminary support member positioned around the second dummy area by irradiating a laser onto the preliminary support member; and
forming a display panel and a support member having an end surface positioned on a virtual plane comprising an end surface of the display panel by irradiating another laser onto the preliminary support member, and by concurrently removing the first dummy area of the preliminary display panel and the second dummy area of the preliminary support member.

2. The method of claim 1, wherein the support member comprises,
a central portion having a flat bottom surface; and
an edge portion comprising the end surface of the support member, and a connection surface connecting the end surface of the support member and the flat bottom surface of the central portion.

3. The method of claim 2, wherein a thickness of the central portion of the support member is different from a thickness of the edge portion of the support member.

4. The method of claim 3, wherein the thickness of the central portion of the support member is greater than the thickness of the edge portion of the support member.

5. The method of claim 3, wherein the thickness of the central portion of the support member is greater than or equal to about 90 micrometers and less than or equal to about 250 micrometers.

6. The method of claim 3, wherein a minimum thickness of the edge portion of the support member is less than or equal to about 20 micrometers.

7. The method of claim 2, wherein the connection surface of the support member has an inclined cross-sectional shape.

8. The method of claim 2, wherein the connection surface of the support member has a stepped cross-sectional shape.

9. The method of claim 1, wherein the support member comprises metal.

10. The method of claim 1, wherein the support member comprises fiber reinforced plastic.

11. A display device comprising:
a display panel comprising a light-emitting element above a substrate; and
a support member under the display panel, and having an end surface on a virtual plane with an end surface of the display panel.

12. The display device of claim 11, wherein the support member comprises:
a central portion having a flat bottom surface; and
an edge portion comprising the end surface of the support member, and a connection surface connecting the end surface of the support member and the flat bottom surface of the central portion.

13. The display device of claim 12, wherein a thickness of the central portion of the support member is different from a thickness of the edge portion of the support member.

14. The display device of claim 13, wherein the thickness of the central portion of the support member is greater than the thickness of the edge portion of the support member.

15. The display device of claim 13, wherein the thickness of the central portion of the support member is greater than or equal to about 90 micrometers and less than or equal to about 250 micrometers.

16. The display device of claim 13, wherein a minimum thickness of the edge portion of the support member is less than or equal to about 20 micrometers.

17. The display device of claim 12, wherein the connection surface of the support member has an inclined cross-sectional shape.

18. The display device of claim 12, wherein the connection surface of the support member has a stepped cross-sectional shape.

19. The display device of claim 11, wherein the support member comprises metal.

20. The display device of claim 11, wherein the support member comprises fiber reinforced plastic.
